(19) United States
(12) Patent Application Publication
(10) Pub. No.: US 2005/0149830 A1
(43) Pub. Date: Jul. 7, 2005

(54) Satellite controlling system having function of distributing satellite state data based on reception environment and method thereof

(76) Inventors: Hee-Sook Mo, Daejon (KR); Won-Chan Jung, Daejon (KR); Jae-Hoon Kim, Daejon (KR)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 10/994,100

(22) Filed: Nov. 19, 2004

(30) Foreign Application Priority Data
Dec. 3, 2003 (KR) 2003-87376

(51) Int. Cl. G01R 31/28; H03M 13/00

(52) U.S. Cl. 714/776

(57) ABSTRACT

Provided are a satellite controlling system having a function of distributing satellite state data based on a reception environment and a method thereof. The satellite controlling system distributes and transmits satellite state data transmitted from a satellite according to preference and authority of the user and the characteristics of a terminal registered by the receiver. The satellite controlling system includes: a satellite signal receiving unit, a data extracting unit, a data processing unit, a data distributing unit; a remote command transmitting unit and a flight dynamics and mission planning unit.

### FIELD OF THE INVENTION

The present invention relates to a satellite controlling system having a function of distributing satellite state data based on a reception environment and a method thereof; and, more particularly, to a satellite controlling system that can distribute and transmit satellite state data transmitted from a satellite according to preference and authority of a receiver and characteristics of a terminal registered by the receiver based on a reception environment, and a method thereof.

### DESCRIPTION OF RELATED ART

A satellite controlling system for operating a satellite from blast-off to the end of its life as a satellite sends out a remote command to the satellite to control the state of the satellite to execute a mission or control the satellite state. Then, an operator examines the state of the satellite by monitoring satellite state data transmitted in real-time from the satellite with a plurality of display screens and prepares for an emergency.

Herein, the satellite state data are check point values for equipment of sub-systems constituting the satellite of a system, and a satellite processor performs sampling on the check point values periodically and transmits the result to a satellite controlling system on the earth. The satellite state data are variable according to a satellite system and a satellite system has a thousand of check point values approximately.

The operator who monitors the state of a satellite is composed of a system engineer for determining and settling an emergency or abnormal situation of the satellite and a satellite operator and a manager that operates a satellite system engineer and a satellite generally. However, a sub-system engineer of each satellite participates in the operation from the moment the satellite is blasted off until it enters its missionary orbit.

Therefore, many satellite operation agents gather in a satellite controlling station and monitor satellite state parameters that vary in real-time through limited monitoring screens in order to cope with a possible emergency quickly. Herein, there is a restriction that monitoring devices, i.e., terminals, should be equipped with system software and application software needed for the display environment of the satellite state parameters.

Hereafter, a conventional satellite controlling system will be described with reference to FIG. 1. As shown, the conventional satellite controlling system comprises a satellite 11, an antenna 12, a signal receiving block 13, a data extracting block 14, a data processing block 15, a data transmitting block 16, a remote command transmitting block 17, and a flight dynamics and mission planning block 18.

The antenna 12 communicates the satellite controlling system with the satellite 11 wirelessly. The signal receiving block 13 receives a frame-based satellite state signal from the satellite 11 periodically. The data extracting block 14 extracts satellite state data, which are to be satellite state parameters, from the frame-based satellite state signal received based on satellite state frame structure database information in the signal receiving block 13.

The data processing block 15 converts the satellite state data extracted in the data extracting block 14 into values that express the state of the satellite 11 substantially, that is, values of an engineering unit such as analog measurement values or state values. The data transmitting block 16 transmits the values of an engineering unit obtained from the conversion in the data processing block 15 to each terminal 19.

The remote command transmitting block 17 transmits a control signal for controlling the satellite 11. The flight dynamics and mission planning block 18 analyzes the orbit and position (posture) data of the satellite 11 and sets up a mission to be executed.

The conventional satellite controlling system has a problem that the packet size of satellite state data is large because the satellite state data transmitted from the satellite 11 are transmitted collectively regardless of the characteristics of receivers and terminals. Since a large volume of data packets come to flow in a network, the load on the network is increased, which hinders smooth transmission of satellite state data.

In addition, all terminals should be high-performance terminals to display all satellite state data and they should be equipped with all the necessary hardware and software of the satellite controlling system.

### SUMMARY OF THE INVENTION

It is, therefore, an object of the present invention to provide a satellite controlling system that can distribute and transmit satellite state data transmitted from a satellite according to the preference and authority of a receiver and characteristics of a terminal pre-registered by a receiver based on a reception environment, and a method thereof.

In accordance with an aspect of the present invention, there is provided a satellite controlling system which includes a satellite signal receiving unit for receiving frame-based satellite state signals from the satellite through a telemetering channel; a data extracting unit for extracting satellite state data, which are to be satellite state parameters, from the frame-based satellite state signals received in the satellite signal receiving unit based on satellite state frame structure database information; a data processing unit for converting the satellite state data extracted in the data extracting unit into values of an engineering unit; a data distributing unit for classifying the values of an engineering unit, which are obtained in the data processing unit, according to environmental conditions of each receiver who logs in, converts the values of an engineering unit according to the characteristics of a terminal of the receiver and distributes the converted values to the terminal; a remote command transmitting unit for transmitting a control signal for controlling the satellite through the antenna; and a flight dynamics and mission planning unit for analyzing orbit and position (posture) data of the satellite and establishing a mission to be executed.

In accordance with another aspect of the present invention, there is provided a method for distributing satellite state data based on a reception environment, which includes the steps of: a) receiving a frame-based satellite state signal from a satellite through a telemetering channel; b) extracting satellite state data, which are to be satellite state parameters, from the frame-based satellite state signals; c) converting the extracted satellite state data into values of an engineering unit; and d) classifying the values of an engineering unit according to environmental conditions of each receiver who logs in, converting the values of an engineering unit according to characteristics of a terminal of the receiver, and distributing the converted values to the terminal.

### BRIEF DESCRIPTION OF THE DRAWINGS

The above and other objects and features of the present invention will become apparent from the following description of the preferred embodiments given in conjunction with the accompanying drawings, in which:

FIG. 1 is a block diagram showing a conventional satellite controlling system in accordance with an embodiment of a prior art;

FIG. 2 is block diagram describing a satellite controlling system having a function of distributing satellite state data based on a reception environment in accordance with an embodiment of the present invention;

FIG. 3 is a block diagram illustrating a data distributing block in accordance with an embodiment of the present invention;

FIG. 4 is a flowchart describing a method of distributing satellite state data based on a reception environment in accordance with an embodiment of the present invention; and

FIG. 5 is a diagram depicting software loaded on a terminal in accordance with the present invention.

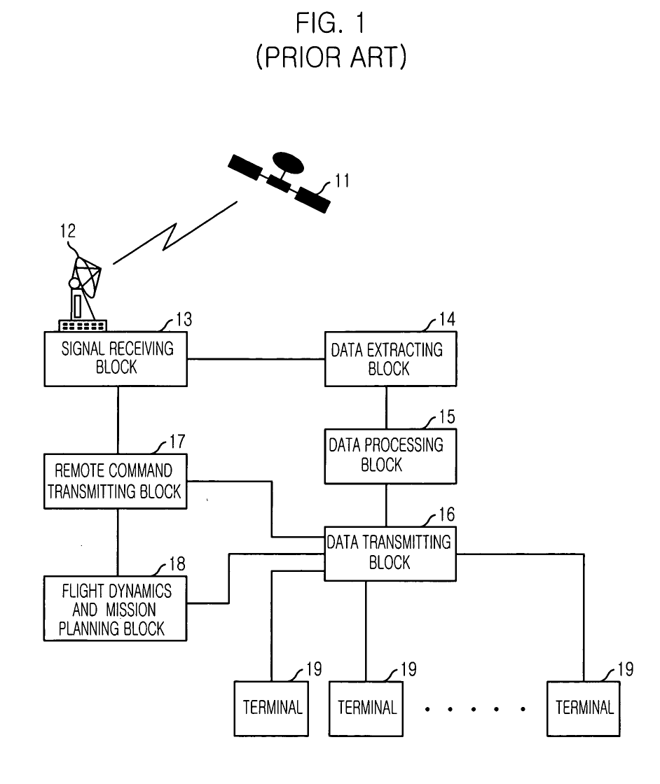

### DETAILED DESCRIPTION OF THE INVENTION

Other objects and aspects of the invention will become apparent from the following description of the embodiments with reference to the accompanying drawings, which is set forth hereinafter.

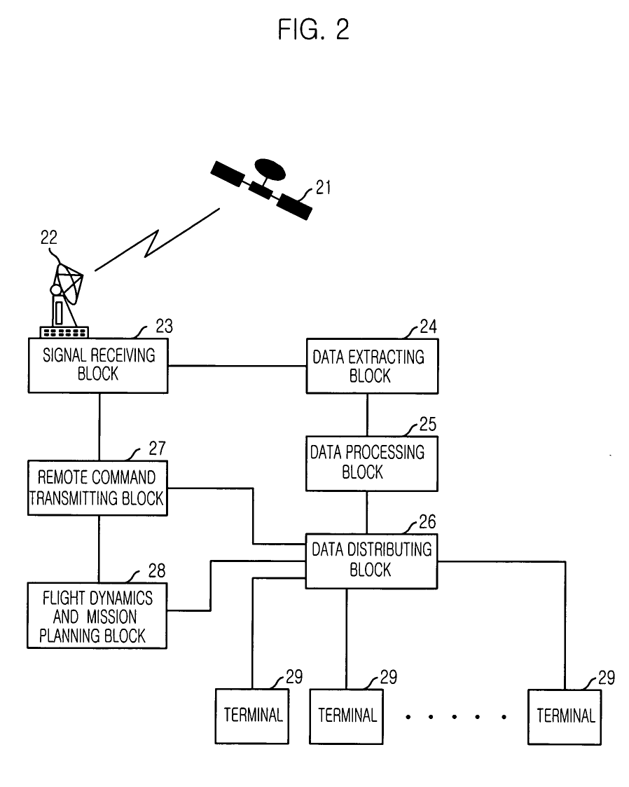

FIG. 2 is block diagram describing a satellite controlling system having a function of distributing satellite state data based on a reception environment in accordance with an embodiment of the present invention.

As shown, the satellite controlling system having a function of distributing satellite state data based on a reception environment comprises: a satellite 21, an antenna 22, a signal receiving block 23, a data extracting block 24, a data processing block 25, a data distributing block 26, a remote command transmitting block 27, and a flight dynamics and mission planning block 28.

The antenna 22 communicates with the satellite 21 wirelessly. The signal receiving block 23 receives a frame-based satellite state (which is telemetered) signal from the satellite 21 through a telemetering channel of the antenna 22 periodically. The data extracting block 24 extracts satellite state data, which becomes a parameter for the satellite state, based on satellite state frame structure database (not shown) information from the frame-based satellite state signal received in the signal receiving block 23. The data processing block 25 converts the satellite state data extracted in the data extracting block 24 into values indicating the substantial state of the satellite, i.e., values of an engineering unit such as an analog measurement value or a state value. The data distributing block 26 classifies the values of an engineering value obtained in the data processing block 25 according to environmental conditions of log-in users, converts them based on the characteristics of user terminals 29, and distributes the converted values to each of the terminals 29. The remote command transmitting block 27 transmits a satellite control signal for controlling the satellite 21 through the antenna 22. The flight dynamics and mission planning block 28 analyzes the orbit and position (posture) data of the satellite 21, and sets up the mission to be implemented.

Herein, the environmental conditions of log-in users indicate information desired by a receiver, such as, information related to each satellite sub system for a satellite sub-system engineer; overall satellite system operation state information for a satellite operation general manager, instead of detailed satellite equipment state information; information (e.g., state value) of a Telementary Command and Ranging (TC&R) sub-system for checking whether a remote command for the satellite is received well for an operator which makes remote commands directly to the satellite.

Also, the environmental conditions of the terminals in which the diverse receivers can check information received from the satellite are conditions for the characteristics of each terminal, i.e., conditions based on the characteristics of devices, such as a desktop computer, a laptop computer, a work station, a Personal Digital Assistant (PDA), a wall display and the like. For example, if a receiver desires to receive satellite state data by using a PDA, the data distributing block 26 converts the satellite state data by controlling font and item numbers in agreement with the display environment of the PDA to thereby output the satellite state data on a monitoring screen of a limited size.

Meanwhile, the values of an engineering unit include a temperature value, a current value, a voltage value, a latitude value, a longitude value.

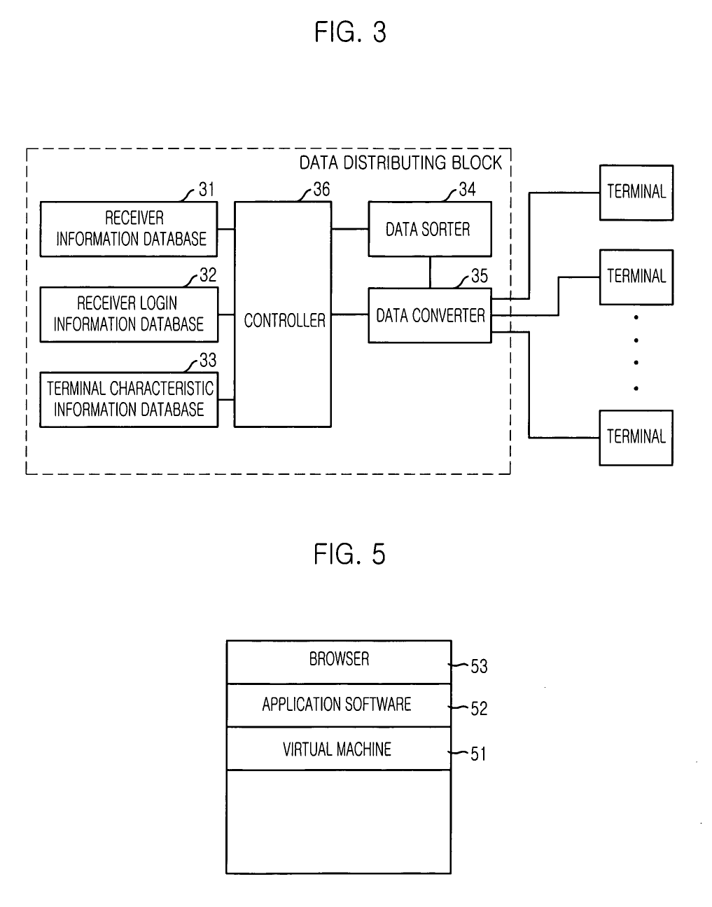

FIG. 3 is a block diagram illustrating the data distributing block 26 in accordance with an embodiment of the present invention. As shown, the data distributing block 26 comprises a receiver information database 31, a receiver log-in information database 32, a terminal characteristic information database 33, a data sorter 34, a data converter 35, and a controller 36.

The receiver information database 31 stores information on the preference and authority of each receiver. The receiver log-in information database 32 stores information on the currently logging-in receivers. The terminal characteristic information database 33 stores terminal characteristic information registered by a receiver of the receiver information database 31. The data sorter 34 forms a satellite state data transmission frame based on the control of the controller 36 by classifying the values of an engineering unit according to the preference and authority of the currently logging-in receiver. The data converter 35 converts the satellite state data transmission frame which is formed in the data sorter 34 in agreement with the characteristics of receiver characteristics. As the satellite state data are inputted, the controller 36 controls the data sorter 34 and the data converter 35 to classify and convert the satellite state data by checking the currently logging-in receiver and the characteristics (i.e., a format type) of the pre-registered terminal through the receiver log-in information database 32 and the terminal characteristic information database 33.

Herein, the present invention can be embodied by integrating the receiver information database 31, the receiver log-in information database 32, and the terminal characteristic information database 33 into one database.

Further, since the satellite controlling system processes all the process for distributing the satellite state data in the present invention, the terminals can check the desired satellite state data only with a minimum interface processing without additional process.

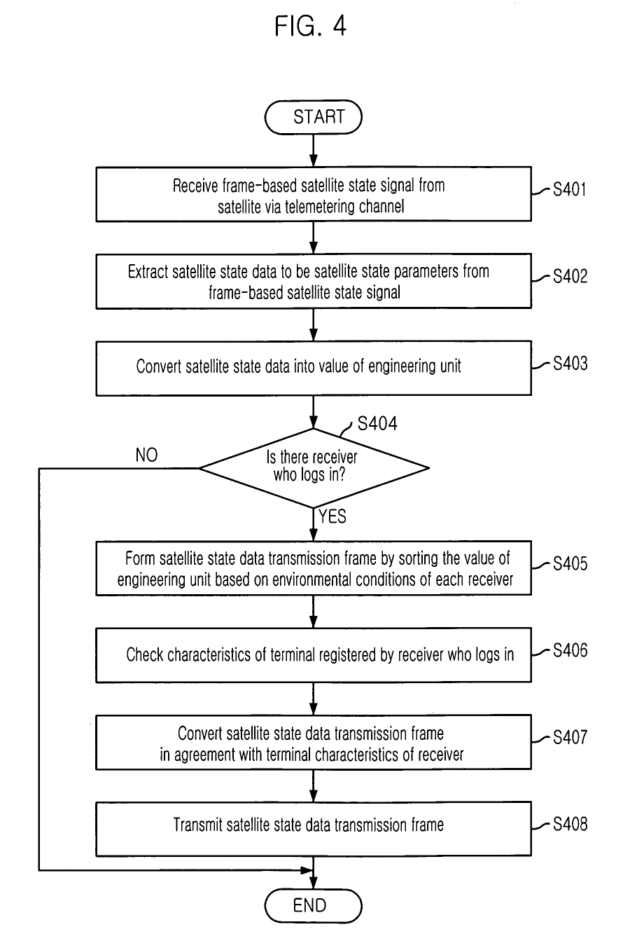

FIG. 4 is a flowchart describing a method of distributing satellite state data based on a reception environment in accordance with an embodiment of the present invention.

First, receivers having an authority for checking the satellite state data are registered in the receiver information database 31 of the satellite controlling system. The receivers access to the satellite controlling system through a log-in process and, herein, information on the user who logs in is stored in the receiver log-in information database 32. Also, the terminal characteristic information database 33 stores terminal characteristic information pre-established by the users registered in the receiver information database 31.

Subsequently, at step S401, the signal receiving block 23 receives a frame-based satellite state signal from the satellite 21 through a telemetering channel. At step S402, the data extracting block 24 extracts satellite state data, which become a parameter for the satellite state, from the frame-based satellite state signal. At step S403, the data processing block 25 converts the extracted satellite state data into values of an engineering unit.

Subsequently, at step S404, the data distributing block 26 checks out whether the logging-in receiver exists. If the receiver does not exist, the logic flow is ended. If the receiver exists, at step S405, a satellite state data transmission frame is formed by classifying the value of an engineering unit based on the environmental conditions of each receiver, that is, based on the desired satellite state data and given authority. Also, at step S406, the characteristics of the terminal registered by the log-in receiver checks are checked and, at step S407, the satellite state data transmission frame is converted in agreement with the terminal characteristics of the receiver. Herein, if the satellite state data transmission frame is agreed with the terminal characteristics of the receiver, the conversion process is not performed.

Subsequently, at step S408, the satellite state data transmission frame is transmitted to the terminal of the receiver. Herein, the terminal of the receiver is equipped with software having a function of displaying the satellite state data transmission frame. If it does not have the software, it can receive the software from the satellite controlling system.

FIG. 5 is a diagram depicting software loaded on a terminal in accordance with the present invention. As shown, the terminal of the present invention includes a virtual machine 51, application software 52, and a browser 53 of graphic and window environment.

The virtual machine 51 implements the application software regardless of hardware and an operating system. The application software 52 displays the satellite state data transmitted from the satellite controlling system in the form of byte codes.

Therefore, the terminal does not have to equip all the software required based on the hardware and software of the satellite controlling system but, if necessary, it can receive the software and display the satellite state data.

In accordance with the present invention, small-sized terminals such as PDA equipped with a minimum function of display only can receive satellite state data by processing and distributing the satellite state data.

Also, the technology of the present invention makes it possible for a plurality of agents to monitor satellite state data simultaneously by processing and distributing of satellite state data in the satellite controlling system and receiving the satellite state data with a small-sized terminal equipped with a minimum function of display.

Further, since the satellite state data are converted in agreement with the characteristics of the terminal, i.e., format type, in the present invention and transmitted to the terminal, it is not necessary to form the terminal according to the environment of the satellite controlling system.

Further, in the present invention, since the terminal for receiving the satellite state data can display the satellite state data by using virtual machine, it needs not to equip software suitable for the application software environment of the satellite controlling system.

Further, since a small-sized terminal having a minimum function of display only can receive the satellite state data through the function of processing and- distributing satellite state data, there is an effect that the satellite controlling system is extended with a small quantity of time and cost.

The present application contains subject matter related to Korean patent application No. 2003-0087376, filed in the Korean Intellectual Property Office on Dec. 3, 2003, the entire contents of which is incorporated herein by reference.

While the present invention has been described with respect to certain preferred embodiments, it will be apparent to those skilled in the art that various changes and modifications may be made without departing from the scope of the invention as defined in the following claims.

1. A satellite controlling system having a function of distributing satellite state data based on a reception environment, comprising:
a satellite signal receiving means for receiving frame-based satellite state signals from the satellite through a telemetering channel;
a data extracting means for extracting satellite state data, which are to be satellite state parameters, from the frame-based satellite state signals received in the satellite signal receiving means based on satellite state frame structure database inforamtion;
a data processing means for converting the satellite state data extracted in the data extracting means into values of an engineering unit;
a data distributing means for classifying the values of an engineering unit, which are obtained in the data processing means, according to environmental conditions of each receiver who logs in; converts the values of an engineering unit according to the characteristics of a terminal of the receiver and distributes the converted values to the terminal;
a remote command transmitting means for transmitting a control signal for controlling the satellite; and
a flight dynamics and mission planning means for analyzing orbit and position (posture) data of the satellite and establishing a mission to be executed.

2. The satellite controlling system as recited in claim 1, wherein the data distributing means includes:
a receiver information database for storing information on preference and authority of each receiver;
a receiver log-in information database for storing information on the receiver who logs in;
a terminal characteristic information database for storing characteristics information of a terminal registered by the receiver;
a data sorting unit for forming a satellite state data transmission frame by classifying the values of an engineering unit based on the preference and authority of the receiver who logs in;
a data converting unit for converting the satellite state data transmission frame formed in the data sorting unit in agreement with the characteristics of the terminal of the receiver; and
a controller for controlling the data sorting unit and the data converting unit to check the receiver who logs in and the characteristics of the terminal registered by the receiver and to classify and convert the satellite state data, as the satellite state data are inputted.

3. The satellite controlling system as recited in claim 1, wherein the terminal includes:
virtual machine for executing application software without being influenced by hardware and an operating system;
application software for displaying the satellite state data transmitted from the satellite controlling system in a format of byte codes; and
a browser of graphic and Windows environment,
wherein the terminal receives software suitable for hardware and software of the satellite controlling system and displays the satellite state data based on the software.

4. A method for distributing satellite state data based on a reception environment, comprising the steps of:
a) receiving a frame-based satellite state signal from a satellite through a telemetering channel;
b) extracting satellite state data, which are to be satellite state parameters, from the frame-based satellite state signals;
c) converting the extracted satellite state data into values of an engineering unit; and
d) classifying the values of an engineering unit according to environmental conditions of each receiver who logs in, converting the values of an engineering unit according to the characteristics of a terminal of the receiver, and distributing the converted values to the terminal.

5. The method as recited in claim 4, wherein the step d) includes the steps of:
d1) forming a satellite state data transmission frame by classifying the values of an engineering unit according to environmental conditions of each receiver, if there is a receiver who logs in;
d2) checking characteristics of a terminal registered by the receiver;
d3) converting the satellite state data transmission frame in agreement with the characteristics of the terminal; and
d4) transmitting the converted satellite state data transmission frame into the receiver terminal.
